(19) United States
(12) Patent Application Publication
(10) Pub. No.: US 2025/0086335 A1
(43) Pub. Date: Mar. 13, 2025

(54) SYSTEM AND METHOD FOR THREE-DIMENSIONAL BUILDING VISUALIZATION AND SIMULATION USING DIGITAL TWINS

(71) Applicant: The Joan and Irwin Jacobs Technion-Cornell Institute, New York, NY (US)

(72) Inventors: Sharon Malka AYALON, New York, NY (US); Daphna LEVINE, New York, NY (US)

(73) Assignee: THE JOAN AND IRWIN JACOBS TECHNION-CORNELL INSTITUTE, New York, NY (US)

(21) Appl. No.: 18/672,728

(22) Filed: May 23, 2024

Related U.S. Application Data
(60) Provisional application No. 63/581,077, filed on Sep. 7, 2023.

(51) Int. Cl. G06F 30/13; G06F 30/12

(52) U.S. Cl. CPC G06F 30/13; G06F 30/12

(57) ABSTRACT

Systems and methods for creating and utilizing digital twins for three-dimensional building visualization and simulations. A method includes parsing tabular data associated with a building. Units represented in the tabular data may be assigned unit class data structures, where each unit class data structure stores data for its respective assigned unit. Data for each unit identified via the parsing may be stored in the respective unit class data structure for that unit. A digital twin is linked to the tabular data with respect to the unit class data structures. Building data for the building is analyzed to identify polylines in the building. Each polyline is extruded to create a 3D model of each unit. In the 3D model, each unit is converted into a mesh. A digital twin of the building is created and linked to at least a portion of the tabular data.

### CROSS-REFERENCE TO RELATED APPLICATIONS

The application claims the benefit of U.S. Provisional Patent Application No. 63/581,077 filed on Sep. 7, 2023, the contents of which are hereby incorporated by reference.

### TECHNICAL FIELD

The present disclosure relates generally to visualization and simulation of three-dimensional models, and more specifically to managing digital twins of three-dimensional models which may be used for visualization and simulation based on tabular data.

### BACKGROUND

In the modern era of building development and management, some entities are seeking to optimize development projects and management using computer software support tools. For example, computer software may be utilized to provide enhanced management of real estate projects. How to leverage and process data for such purposes in an efficient and optimized manner is a technical challenge which hinders further progress in this field. Accordingly, solutions for improved building development and management using computer software, particularly solutions which optimize data usage and processing, would therefore be highly desirable.

### SUMMARY

A summary of several example embodiments of the disclosure follows. This summary is provided for the convenience of the reader to provide a basic understanding of such embodiments and does not wholly define the breadth of the disclosure. This summary is not an extensive overview of all contemplated embodiments, and is intended to neither identify key or critical elements of all embodiments nor to delineate the scope of any or all aspects. Its sole purpose is to present some concepts of one or more embodiments in a simplified form as a prelude to the more detailed description that is presented later. For convenience, the term “some embodiments” or “certain embodiments” may be used herein to refer to a single embodiment or multiple embodiments of the disclosure.

Certain embodiments disclosed herein include a method for creating a digital twin using tabular data. The method comprises: parsing tabular data representing a plurality of units of a building in order to identify the plurality of units represented in the tabular data; assigning a unit class data structure of plurality of unit class data structures to each unit of the identified plurality of units, wherein the unit class data structure assigned to each unit stores data for the unit, wherein the unit class data structure assigned to each unit includes at least one field representing at least one characteristic of the unit; generating a digital twin of the building based on the plurality of unit class data structures and building data for the building, wherein the building data at least represents three-dimensional aspects of the building; and linking the digital twin to the tabular data based on the plurality of unit class data structures, wherein at least one portion of the digital twin is linked to at least one portion of the tabular data, wherein each linked portion of the tabular data represents a unit of the plurality of units.

Certain embodiments disclosed herein also include a non-transitory computer readable medium having stored thereon causing a processing circuitry to execute a process, the process comprising: parsing tabular data representing a plurality of units of a building in order to identify the plurality of units represented in the tabular data; assigning a unit class data structure of plurality of unit class data structures to each unit of the identified plurality of units, wherein the unit class data structure assigned to each unit stores data for the unit, wherein the unit class data structure assigned to each unit includes at least one field representing at least one characteristic of the unit; generating a digital twin of the building based on the plurality of unit class data structures and building data for the building, wherein the building data at least represents three-dimensional aspects of the building; and linking the digital twin to the tabular data based on the plurality of unit class data structures, wherein at least one portion of the digital twin is linked to at least one portion of the tabular data, wherein each linked portion of the tabular data represents a unit of the plurality of units.

Certain embodiments disclosed herein also include a system for creating a digital twin using tabular data. The system comprises: a processing circuitry; and a memory, the memory containing instructions that, when executed by the processing circuitry, configure the system to: parse tabular data representing a plurality of units of a building in order to identify the plurality of units represented in the tabular data; assign a unit class data structure of plurality of unit class data structures to each unit of the identified plurality of units, wherein the unit class data structure assigned to each unit stores data for the unit, wherein the unit class data structure assigned to each unit includes at least one field representing at least one characteristic of the unit; generate a digital twin of the building based on the plurality of unit class data structures and building data for the building, wherein the building data at least represents three-dimensional aspects of the building; and link the digital twin to the tabular data based on the plurality of unit class data structures, wherein at least one portion of the digital twin is linked to at least one portion of the tabular data, wherein each linked portion of the tabular data represents a unit of the plurality of units.

Certain embodiments disclosed herein include the method, non-transitory computer readable medium, or system noted above, further including or being configured to perform the following step or steps: checking a value indicated in each field of at least one first unit class data structure of the plurality of unit class data structures; and generating a visualization of the digital twin based on the digital twin and each checked value.

Certain embodiments disclosed herein include the method, non-transitory computer readable medium, or system noted above, further including or being configured to perform the following step or steps: checking a value indicated in each field of at least one first unit class data structure of the plurality of unit class data structures; and running at least one simulation for the digital twin based on the digital twin and each checked value.

Certain embodiments disclosed herein include the method, non-transitory computer readable medium, or system noted above, further including or being configured to perform the following step or steps: analyzing the building data for the building in order to identify a plurality of polylines of the building, wherein each polyline is a vector line including at least one connected line segment, wherein the at least one connected line segment of each polyline forms a shape.

Certain embodiments disclosed herein include the method, non-transitory computer readable medium, or system noted above, further including or being configured to perform the following step or steps: extruding each of the plurality of polylines in order to create a plurality of three-dimensional (3D) models of the plurality of units, wherein the digital twin is generated based further on the plurality of 3D models of the plurality of units.

Certain embodiments disclosed herein include the method, non-transitory computer readable medium, or system noted above, further including or being configured to perform the following step or steps: coding the plurality of 3D models with a plurality of names, wherein the plurality of names is determined based on a plurality of identifiers of the plurality of units indicated in the tabular data.

Certain embodiments disclosed herein include the method, non-transitory computer readable medium, or system noted above, further including or being configured to perform the following step or steps: matching the plurality of units to respective portions of the building data based on the plurality of polylines, wherein the digital twin is created based on the matching between the plurality of units and the respective portions of the building data.

Certain embodiments disclosed herein include the method, non-transitory computer readable medium, or system noted above, further including or being configured to perform the following step or steps: generating a plurality of grouping class data structures based on the plurality of unit class data structures, wherein each grouping class data structure represents a subset of the unit class data structures, wherein changes made with respect to each grouping class data structure are applied to each of the subset of the unit class data structures represented by the grouping class data structure; and applying a change to a first grouping class data structure of the plurality of grouping class data structures.

Certain embodiments disclosed herein include the method, non-transitory computer readable medium, or system noted above, further including or being configured to perform the following step or steps: accessing the digital twin, wherein accessing the digital twin further comprises populating the digital twin with data from each of the linked at least one portion of the tabular data.

Certain embodiments disclosed herein include the method, non-transitory computer readable medium, or system noted above, further including or being configured to perform the following step or steps: generating a condition report based on the digital twin and at least one action item input, wherein the condition report indicates a condition of at least one portion of the building.

Certain embodiments disclosed herein include the method, non-transitory computer readable medium, or system noted above, further including or being configured to perform the following step or steps: updating at least a portion of the tabular data based on at least one action item input, wherein the condition report is generated based further on the updated at least a portion of the tabular data.

Certain embodiments disclosed herein include the method, non-transitory computer readable medium, or system noted above, further including or being configured to perform the following step or steps: generating at least one user interface component based on the condition report, wherein at least a portion of the at least one user interface component is visually distinguished based on the condition of the at least one portion of the building indicated by the condition report.

### BRIEF DESCRIPTION OF THE DRAWINGS

The subject matter disclosed herein is particularly pointed out and distinctly claimed in the claims at the conclusion of the specification. The foregoing and other objects, features, and advantages of the disclosed embodiments will be apparent from the following detailed description taken in conjunction with the accompanying drawings.

FIG. 1 is a network diagram utilized to describe various disclosed embodiments.

FIG. 2 is a flowchart illustrating a method for optimizing renovation using a digital twin according to an embodiment.

FIG. 3 is a flowchart illustrating a method for creating a digital twin using tabular data according to an embodiment.

FIG. 4 is a flowchart illustrating a method for generating user interfaces based on condition reports defined with respect to a digital twin according to an embodiment.

FIG. 5 is an example illustration of a digital twin integrated with tabular data.

FIG. 6 is an example illustration of a renovation schedule integrating action items.

FIG. 7 is a schematic diagram of a visualizer according to an embodiment.

### DETAILED DESCRIPTION

The various disclosed embodiments include methods and system for three-dimensional building visualization and simulations using digital twins. More specifically, using digital twins linked to tabular data. The disclosed embodiments include various techniques for creating and managing digital twins based on tabular data, and may be utilized in order to optimize schedules defined with the digital twins. For example, work on units represented in the digital twin may be prioritized based on the digital twin and tabular data. Further, various disclosed embodiments allow for updating digital twins in real-time using tabular data.

In an embodiment, tabular data representing units in a building and building data indicating characteristics of a building to be represented by a digital twin. To this end, the tabular data may include, but is not limited to, one or more digital spreadsheets or portions thereof. The building data may include, but is not limited to, floor plan data, three-dimensional building structure data (e.g., data representing shape, form, etc.), both, and the like.

The tabular data is parsed in order to convert data among the tabular data into formats and types which are designed to facilitate integration with digital twins in accordance with various disclosed embodiments. More specifically, units represented in the tabular data may be assigned unit class data structures, where each unit class data structure stores data for its respective assigned unit.

The unit class data structures may further be aggregated and controlled together in groups according to a structure of the building. To this end, the unit class data structures may be organized into a grouping class data structure such as, but not limited to, a floor class data structure including unit class data structures of units among a floor of the building. Such a grouping class data structure may be utilized in order to efficiently apply changes to all units among the grouping class data structure. Different class data structures (e.g., unit class data structures and grouping class data structures) may have associated therewith respective sets of instructions for manipulating properties among data of the class data structure, thereby allowing for customizing control of the class data structures with respect to the parts of the building they represent. As a non-limiting example, each unit class data structure is associated with sets of instructions for reading and writing data within the unit class data structure, and each floor class data structure is associated with a set of instructions for accessing values within unit data structures among the floor class data structure.

To this end, data for each unit identified via the parsing may be stored in the respective unit class data structure for that unit. The unit class data structures may be formatted in order to facilitate integration with digital twins, for example, by organizing data related to each unit such that, for example, certain fields in a given unit class data structure represent certain characteristics of the respective unit that are related to digital twin visualization, simulation, or both. Consequently, a digital twin linked to the tabular data may be linked with respect to the unit class data structures such that the visual appearance or other visualization or simulation characteristics of each unit in a digital twin are modified in accordance with the respective fields of the unit class data structures for the respective unit. As a non-limiting example, a value indicated in a field of a unit class data structure corresponding to a status of the respective unit may be checked when the digital twin is to be rendered visually in order to determine a visual marker (e.g., a color) for the unit associated with the status indicated in the status field. Further, different fields may be utilized for different visualization modes such as, but not limited to, visualization modes for visualizing different aspects of the building development or management (e.g., status mode or inspection mode).

In an embodiment, the building data is analyzed to identify polylines in the building. In a further embodiment, each polyline is a vector line including one or more connected line segments (e.g., straight line segments) which collectively make up a shape such as, but not limited to, the outline of a unit. Each polyline is extruded to create a 3D model of each unit which may include, but is not limited to, the locations of windows and other distinctive features of the unit.

In the 3D model, a portion of the 3D model representing each unit is converted into a respective mesh. That is, a 3D representation of the unit is generated as a mesh based on the building data and, in particular, based on the identified polylines. Each mesh may be a 3D model of the respective unit and may be coded with a name compatible with a cell in the tabular data. The compatible names may be determined based on the tabular data, for example, based on identifiers of units indicated in respective fields among the tabular data.

Based on the polylines and the tabular data, the units represented in the tabular data are matched to respective portions of the building data (e.g., respective portions of floor plans including areas enclosed by polylines which represent those units in the 3D model). Based on the matching, a digital twin of the building is created such that the digital twin represents both three-dimensional aspects of the building as well as a layout of the units in the building. The digital twin may therefore serve as a repository for various information about the building. Each unit stores the 3D appearance and form of its real-world twin along with other data related to each unit (e.g., data included among the tabular data). The other data may include, but is not limited to, permit data, special inspections needed, scheduling options, procurements lists, vendors communication, financial data, and so forth.

A digital twin of the building is created based on the tabular data and the building data. The digital twin is linked to at least a portion of the tabular data such that, when visualizations of the digital twin are to be generated or otherwise when the digital twin is utilized to generate other data, data is read from the linked portion of the tabular data as part of the digital twin. Accordingly, the digital twin is effectively automatically updated as the tabular data is updated. Additionally, protocol data related to development of the building may be integrated into the digital twin.

Moreover, the tabular data may store data for units at different points in time, for example indexed by timestamp or otherwise indexed with respect to time. Such data from different points in time may be utilized to populate the digital twin with applicable data based on a given time (i.e., one of the points in time), thereby allowing for visualizing the building using the digital twin populated with data corresponding to a specific point in time. Accordingly, the digital twin may be efficiently modified to represent the building at different points in time, effectively allowing for moving forward and backward in time with respect to development of units in the building.

The digital twin may be utilized to generate a visualization of the building, for example, in the form of one or more visual graphical user interface (GUI) elements to be displayed via a user interface. The visualization may be marked to indicate information related to the units indicated in the tabular data (e.g., a status of each unit), information related to a renovation schedule, both, and the like.

The digital twin may also be utilized in order to generate one or more optimizations with respect to a renovation process for the building. Such optimizations may be defined with respect to units represented in the digital twin and underlying tabular data, for example, by utilizing target data indicating one or more target characteristics for the building represented by the building. As a non-limiting example, a timeline for improvements may be determined based on the digital twin and the target characteristics. Such a timeline may be defined with respect to, for example, action items to be performed pursuant to building improvement, arranged in order from earliest to perform through latest to perform.

The digital twin may further be linked to the tabular data, for example, by linking portions of the digital twin corresponding to units to columns or other portions of the tabular data representing the respective units. Additional data such as, but not limited to, status data (occupancy, renovation timeline and budget, leasing information, and the like) protocol data (order of events and things that need to happen in order to move from one phase to the other), or both, may be integrated into the digital twin, either directly or via the linked tabular data, such that the additional data may be accessed and visualized along with other portions of the digital twin.

In some implementations, different action items may be grouped with respect to phases, where each phase represents a potential state of a unit with respect to improvement of the units and the building. To this end, a condition report defined with respect to characteristics of the building represented in the digital twin which may be relevant to the action items is generated, and may be utilized to provide a user interface visually illustrating the condition report with respect to a visualization of the digital twin.

In addition to efficiencies related to automatically updating the digital twin by populating the digital twin with linked tabular data, linking the digital twin to tabular data as described herein allows for efficiently modifying the digital twin and may be utilized to streamline user interactions for performing such modifications. More specifically, data in the digital twin may be managed via management of the linked tabular data such that updating the linked tabular data also effectively updates the digital twin. Accordingly, the disclosed embodiments allow for minimizing the amount of processing transactions in order to update both the digital twin and the tabular data.

Further, in some embodiments, the digital twin may be updated as needed, for example, when the digital twin is to be rendered or otherwise accessed. In such embodiments, the tabular data may be updated as changes are made without updating the digital twin for each such change, thereby conserving computing resources related to updating the digital twin.

Moreover, various disclosed embodiments utilizing tabular data linked to digital twins effectively allow for leveraging various tools integrated with tabular data management software (e.g., digital spreadsheet management software). Accordingly, various disclosed embodiments enable utilizing such integrated tools in combination with the digital twins, and more specifically can be realized without directly integrating such tools within 3D model software, thereby facilitating using those integrations with the digital twins.

On top of the various technical improvements to digital twin management, processing, and rendering noted above, the technical improvements enable new use cases for digital twin technologies in the realms of real estate and other building management. Specifically, the improved digital twin visualization and simulations enabled by various disclosed embodiments allows for leveraging the digital twins in order to streamline workflows and optimize decision making. Consequently, the disclosed embodiments may be utilized to realize improvements in building management, for example, by optimizing rental occupations.

Moreover, the improved visualization and simulation tools described herein may be utilized to provide improved displays of buildings represented by digital twins which may allow, among other things, for improving communication and coordination between team members through real-time collaboration. For example, the improved efficiency of managing the digital twins via linked tabular data may allow for accelerating presentation the digital twin being displayed to different users in a manner that facilitates real-time updating of the digital twin on the respective users' displays, thereby improving collaboration.

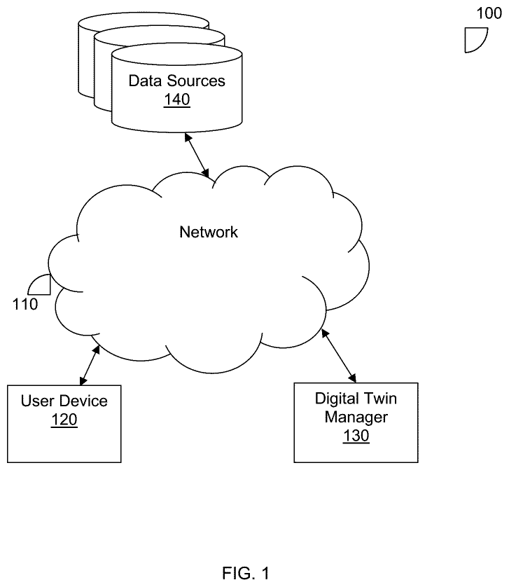

FIG. 1 shows an example network diagram 100 utilized to describe the various disclosed embodiments. In the example network diagram 100, a user device 120, a digital twin manager 130, and a plurality of databases 140-1 through 140-N (hereinafter referred to individually as a database 140 and collectively as databases 140, merely for simplicity purposes) communicate via a network 110.

The network 110 may be, but is not limited to, a wireless, cellular or wired network, a local area network (LAN), a wide area network (WAN), a metro area network (MAN), the Internet, the worldwide web (WWW), similar networks, and any combination thereof.

The user device (UD) 120 may be, but is not limited to, a personal computer, a laptop, a tablet computer, a smartphone, a wearable computing device, or any other device capable of receiving and displaying notifications. In accordance with various disclosed embodiments, the user device 120 may receive visualization data for graphically rendering a visualization of a digital twin, simulation results data for displaying results of simulations related to digital twins, or both, from the digital twin manager 130. Such data received from the digital twin manager 130 may be rendered on a display (not shown) of the user device 120.

The digital twin manager 130 is configured to create and manage digital twins in accordance with one or more of the disclosed embodiments. To this end, the digital twin manager 130 may be configured to retrieve building data, tabular data, or both, from the data sources 140. To this end, the data sources 140 may include databases or other data sources storing such building or tabular data.

The tabular data at least represents units in a building and includes portions corresponding to respective units in floor plan data of the building. To this end, the tabular data may include, but is not limited to, one or more digital spreadsheets or portions thereof such as, for example, but not limited to, tabular data stored in comma separated value (CSV) files. The building data indicates characteristics of a building to be represented by the digital twin and may include, but is not limited to, floor plan data, three-dimensional building structure data (e.g., data representing shape, form, etc.), both, and the like. The floor plan data at least indicates a layout of various units within a building to be represented by the digital twin and may be, but are not limited to, rooms, offices, apartments, combinations thereof, portions thereof, and the like.

The digital twin manager 130 is configured to analyze such data in order to create digital twins and to link digital twins to respective sets of tabular data as described herein. In various disclosed embodiments, the digital twin manager 130 is further configured to utilize the digital twins, for example, by generating visualization data for graphically rendering the digital twins, running simulations and generating simulation data, or both.

It should be noted that a single user device 120 is depicted for simplicity purposes, but that multiple user devices may be equally utilized without departing from the scope of the disclosure. In particular, multiple user devices may receive data related to the same digital twin in order to facilitate collaboration between users of those user devices with respect to the building represented by the digital twin.

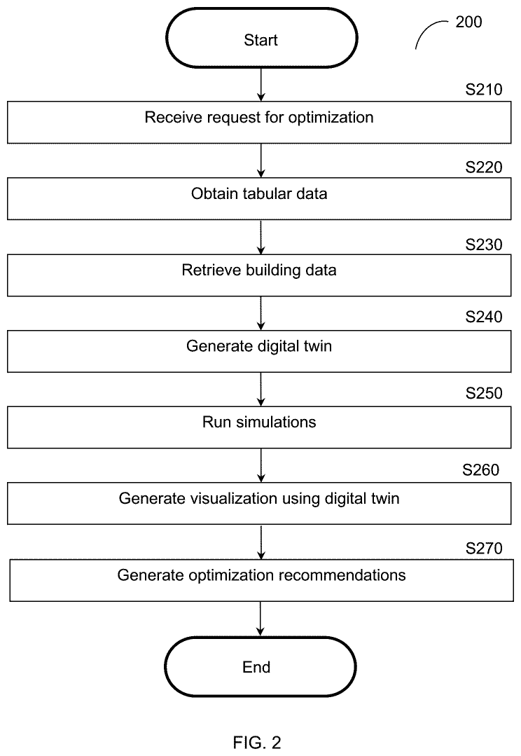

FIG. 2 is a flowchart 200 illustrating a method for optimizing renovation using a digital twin according to an embodiment. In an embodiment, the method is performed by the digital twin manager 130, FIG. 1.

At S210, a request for optimization is received. The request may indicate a building for which optimization is desired and may be received, for example, from a user device (e.g., the user device 120, FIG. 1). In some implementations, the request may further include tabular data for the building, building data for the building, or both.

At S220, tabular data for a building is obtained. The tabular data may be received (e.g., as part of the request received at S210) or retrieved (e.g., based on the building indicated in the request).

In an embodiment, the tabular data at least represents units in a building and includes portions corresponding to respective units in floor plan data of the building. The tabular data may be structured or semi-structured data having fields including values representing respective characteristics of the building, of units in the building, both, and the like. To this end, the tabular data may include, but is not limited to, one or more digital spreadsheets or portions thereof such as, for example, but not limited to, tabular data stored in comma separated value (CSV) files, JavaScript Object Notation (JSON) files, Extensible Markup Language (XML) files, hypertext markup language (HTML) files, combinations thereof, portions thereof, and the like.

In a further embodiment, the tabular data also includes data defining a shape, size, or other structural details of each unit represented therein. Such structural details may be utilized in order to match portions of the tabular data to respective units reflected in the building data (e.g., as defined via polylines) in order to match each unit represented in a three-dimensional model of the building with corresponding tabular data to be used for populating a display with respect to each unit.

At S230, building data related to a building represented by the tabular data is obtained. The building data may be received (e.g., as part of the request received at S210) or retrieved (e.g., based on the building indicated in the request).

In an embodiment, the building data indicates characteristics of a building to be represented by the digital twin and may include, but is not limited to, floor plan data, three-dimensional building structure data (e.g., data representing shape, form, etc.), both, and the like. The floor plan data at least indicates a layout of various units within a building to be represented by the digital twin and may be, but are not limited to, rooms, offices, apartments, combinations thereof, portions thereof, and the like.

At S240, a digital twin is generated based on the tabular data and the building data. To this end, S240 includes analyzing the tabular data and building data in order to identify portions of such data to be used for generating the digital twin. More specifically, the tabular data is analyzed to identify units and the identified units are matched to the building data such that the digital twin may be populated with data representing respective units using matching portions of the building data and tabular data. In an embodiment, S240 further includes linking the generated digital twin to the tabular data such that portions of the tabular data may be retrieved in order to render or otherwise populate the digital twin, for example, when a request to view a visualization or run a simulation of the digital twin is received.

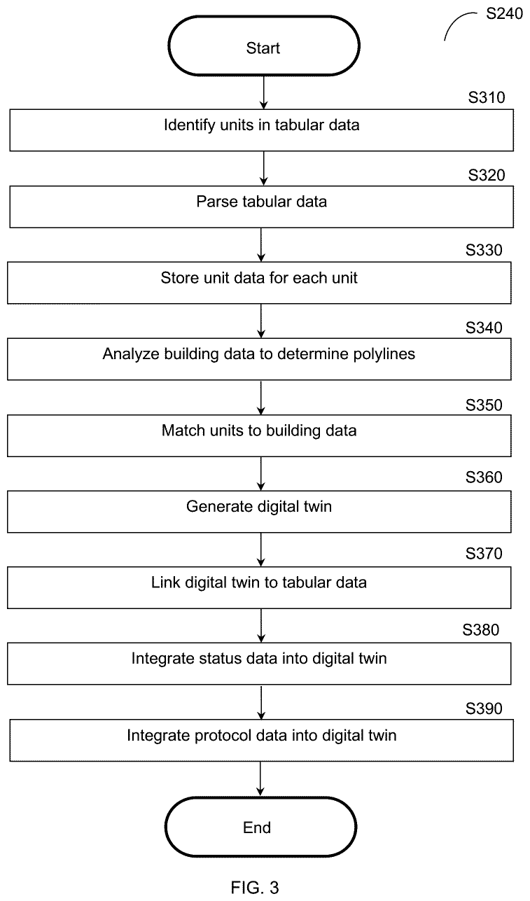

In an embodiment, the digital twin is generated as now described with respect to FIG. 3. FIG. 3 is a flowchart S240 illustrating a method for creating a digital twin using tabular data according to an embodiment.

At S310, units represented in tabular data are identified. In an embodiment, S310 includes applying unit identification rules defined with respect to a structure of the tabular data, e.g., rules defining which sets of data among tabular data represent a unit and its various characteristics. To this end, such unit identification rules may be defined with respect to aspects of tabular data such as, but not limited to, certain portions of the tabular data (e.g., certain fields), markers (e.g., predetermined data flagging or otherwise indicating the beginning or end of a unit's set of data), minimum required data for defining a unit (e.g., requiring that a unit include values for at least a predetermined number of potential unit characteristics or that a unit include values representing certain predetermined characteristics), combinations thereof, portions thereof, and the like.

At S320, the tabular data is parsed. More specifically, the tabular data may be parsed with respect to the identified units in order to identify data for each unit. In an embodiment, S320 includes analyzing the tabular data in order to extract data to be used for creating the digital twin (e.g., predetermined types of data with which the digital twin is to be populated). The parsing of the tabular data may allow for or otherwise facilitate language processing of the tabular data, for example, using natural language processing, in order to analyze the tabular data during subsequent processing.

In a further embodiment, S320 may include converting the format of the parsed data from one format to another. The format into which the parsed data is converted may be a unified format (e.g., such that tabular data from different data sources which may be stored in different formats be transformed into the same format for subsequent processing), and may further be a unified format designed to facilitate populating digital twins as described herein.

In some embodiments, the tabular data may be converted into formats having a structure matching a predetermined structure for data to be used for populating the digital twin in order to facilitate populating the digital twin with the tabular data. That is, rather than requiring analyzing the tabular data each time the digital twin is to be populated with portions the tabular data, portions of the tabular data may be stored in predesignated portions of a unified format structure that correspond to portions of a structure defined in predetermined digital twin population rules, thereby avoiding the need for repeatedly analyzing the tabular data to identify the appropriate portions for use in populating the digital twin.

In yet a further embodiment, S320 also includes validating the parsed data. More specifically, the parsed data is analyzed, with the parsing allowing for determining whether the data conforms to a particular structure or format. In some embodiments, when the parsed data does not conform to a predetermined structure or format, the parsed data may be converted into that predetermined structure or format as described above. Additionally, the validation may further include checking integrity and correctness of the data, for example, using predetermined integrity checking rules. Such integrity checking rules may define expected or otherwise applicable formats for data values such as, but not limited to, defining that a given field should contain a textual value or, more specifically, a textual value formatted in a specific format.

In an example implementation, the tabular data may be stored in a comma separated value (CSV) format, with rows of the tabular data representing corresponding units in a building and data fields in each row including values representing respective characteristics of the corresponding unit. Accordingly, columns of such tabular data may represent unit characteristics such as, but not limited to, unit identifier (ID), room layout, area, pricing, current status, notes provided by a unit owner or operator, and the like. In such an implementation, the tabular data is parsed in order to identify rows as corresponding to respective units and to determine characteristics of each unit based on data in the row representing each unit.

At S330, unit data for each unit is stored. The unit data for each unit includes the data identified by parsing the tabular data as discussed with respect to S320. As noted above, the data for each unit may be stored in a format or structure designed for use in populating digital twins as described herein. The data for each unit may further be associated with the respective unit.

In an embodiment, the unit data is stored in a set of unit class data structures assigned to respective units among the units to be represented for the building. To this end, in a further embodiment, storing the unit data further includes generating the unit class data structures and assigning each unit class data structure to a respective unit among the units represented in the tabular data. In yet a further embodiment, each unit class data structure stores data for a corresponding unit (i.e., the unit to which the unit class data structure is assigned).

In an embodiment, each unit class data structure includes fields representing characteristics of its corresponding assigned unit. Such characteristics may be characteristics indicated within the tabular data. More specifically, the characteristics may be or may include characteristics related to digital twin visualization, simulation, or both. That is, the characteristics include characteristics used for visualization, simulation, or both. The field in each unit class data structure may include the respective portion of data among the tabular data corresponding to the characteristic of the unit represented by that unit class data structure. Alternatively, the field in each unit class data structure may include one or more pointers to one or more locations within the tabular data where the portion of data indicating the corresponding characteristics for the unit is stored. Such pointers may facilitate, for example, generating unit class data structures for tabular data stored in a different storage. That is, each field includes data for the unit, and such data may be a portion of data indicating one or more characteristics of the unit, or a pointer to such a portion of data.

As discussed herein, by storing characteristics in the unit class data structures and linking the digital twin to the tabular data via the unit class data structures, the digital twin may be effectively updated automatically when visualization or simulation is needed. The current data among the tabular data may be checked or otherwise accessed based on the unit class data structures and utilized to populate the data used for visualization or simulation, thereby ensuring that the visualization or simulation is based on the current data. Moreover, because such data may be accessed as needed, i.e., when a visualization is to be generated or simulation is to be performed, the population of the data for the digital twin from the tabular data may also be performed only as needed rather than every time a change is made to the tabular data. This conserves computing resources related to processing and storing the data as well as ensuring that the digital twin is represented accurately based on current data.

In some embodiments, the unit class data structures are aggregated and controlled together in groups. Such groups may be, but are not limited to, defined based on a structure of the building. As a non-limiting example, the groups may be defined with respect to floors, sections of floors, blocks, groups of floors, or other subsets of the building being represented. To this end, in a further embodiment, the unit class data structures may be grouped using one or more grouping class data structures. Each grouping class data structure includes an indication of multiple unit class data structures representing units belonging to the group represented by the grouping class data structure.

To this end, in an embodiment, S330 further includes generating one or more grouping class data structures and assigning a subset of the unit class data structures to each grouping class data structure. Each grouping class data structure may include data indicating its respective assigned unit class data structures. Defining such grouping class data structures may allow, for example, for efficiently applying changes across the group. That is, when a change is made to the unit class data structure for one of the units among the group represented by a grouping class data structure, other unit class data structures to be changed similarly or in the same way may be identified based on the grouping class data structure.

As noted above, different types of class data structures (e.g., unit class data structures are one type and grouping class data structures are another type) may have different associated sets of rules or instructions for manipulating properties among data in the respective type of data structure. These different sets of rules or instructions may effectively allow for leveraging the different types of data structures for purposes of visualization or simulation as discussed herein. As a non-limiting example, rules or instructions for unit class data structures may include rules for updating data of the unit class data structure individually as well as rules for accessing the unit class data structure. As a further non-limiting example, rules or instructions for grouping class data structures may include rules for applying changes made to one of the units among the group represented by the grouping class data structure across other units among the group (e.g., by accessing each unit class data structure assigned to those other units in order to update each unit class data structure's data individually).

Moreover, further subtypes of units and groups may be defined. As a non-limiting example, different kinds of units defined with respect to predetermined unit layouts (e.g., a suite unit may be defined differently from a single room unit). As another non-limiting example, different kinds of groups may be defined with respect to the portions of buildings they represent (e.g., a floor unit may be defined differently than a block). Further defining subtypes may allow for further customizing the rules which are applied to different types of building sub-portions (e.g., units or groups).

At S340, building data representing three-dimensional and other aspects of a building is analyzed in order to determine polylines of the building. The building data represents a building corresponding to the building represented by the tabular data. Each polyline is a vector line including one or more connected line segments that collectively form a shape such as, but not limited to, the outline or other contour of a unit. Each polyline may be extruded when generating or otherwise creating the digital twin in order to create a three-dimensional representation of the respective portion of the building encapsulated by the polyline (e.g., a unit within the outline defined by a polyline).

At S350, the identified units are matched to the building data based on the determined polylines. As noted above, the polylines define outlines of units or other portions of the building. Accordingly, information about the sizes, shapes, orientation, organization, or other aspects of the units which may be reflected by the polylines are utilized to match units indicated in the tabular data to their corresponding counterparts in the building represented by three-dimensional portions of the building data defined via polylines.

At S360, a digital twin is generated based on the building data, the tabular data, and the matching of units between the building data and the tabular data. In an embodiment, creating the digital twin includes extruding the polylines of the building in order to create three-dimensional structures representing the portions of the building encapsulated by the polylines. These three-dimensional structures can then be utilized in order to create a three-dimensional model of the building. The result is a three-dimensional digital twin of the building, including various subparts representing units or other portions of the building. The digital twin may function as a repository for various data of the building, and has components which function as repositories for various data of components of the building (e.g., units).

At S370, the digital twin is linked to the tabular data. In an embodiment, the digital twin is linked to the tabular data such that, when the digital twin is accessed, corresponding data from among the tabular data is retrieved in order to populate data which will be utilized to render a three-dimensional view of the digital twin. To this end, S370 may include, but is not limited to, storing a reference to the tabular data or other data which may be utilized in order to access and retrieve applicable tabular data such that, when the digital twin is to be populated with information included in the tabular data, the applicable portions of the tabular data may be accessed in order to retrieve the appropriate tabular data and use the retrieved data in order to populate the digital twin.

In a further embodiment, the digital twin is linked to the tabular data further with respect to units, groups of units, or both. More granular linking to specific units or groups of units may allow for retrieving portions of the tabular data for use in rendering displays of the digital twin only as needed, thereby conserving computing resources. As a non-limiting example, unit-specific data may only be retrieved from the tabular data when a user interacts with a given unit reflected in a view of the digital twin displayed on a user device rather than requiring retrieving and storing in memory tabular data for all units.

To this end, in such an embodiment, linking the digital twin to the tabular data further includes linking the digital twin to the unit class data structures, to group class data structures, or both. As noted above, such data structures may have corresponding rules instructions for how to access the underlying data, thereby defining how to retrieve the appropriate data to be used for virtualizing or simulating the digital twin via the applicable data structures.

As noted above, by linking the digital twin to the tabular data, the digital twin may be effectively updated by updating the tabular data and without requiring explicitly updating the digital twin. When the digital twin is accessed or otherwise utilized, the digital twin may be populated with the current data from among the linked tabular data. Such linking may therefore reduce consumption of computing resources related to updating the digital twin, particularly when users are collaborating such that the underlying tabular data is updated more frequently than updated digital twins are required.

At optional S380, status data is integrated into the digital twin. The status data may indicate information such as, but not limited to, occupancy, renovation timeline and budget, leasing information and the like. The status data may define a status of the building or any portion thereof, which may be utilized to monitor and manage progress of building development.

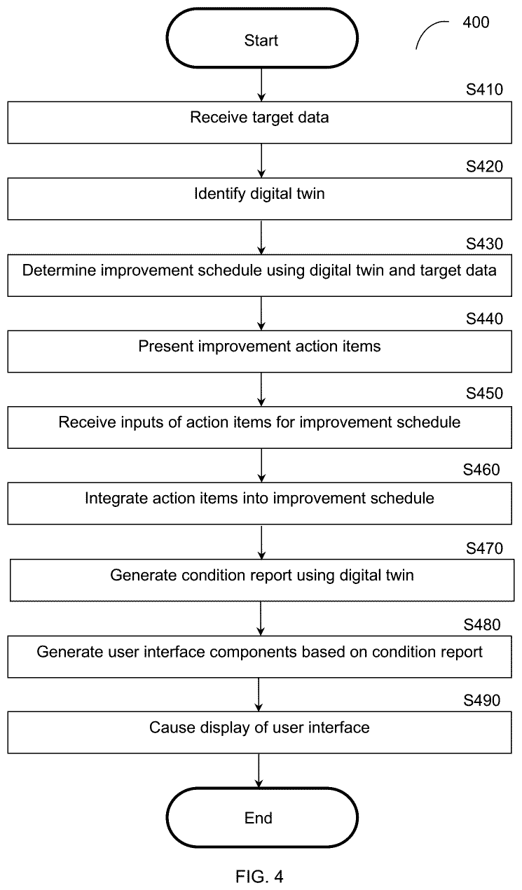

In an embodiment, the status data is defined with respect to action items to be performed in order to move from one state to another for individual units within the building. The action items may further be incorporated into an improvement schedule generated based on the digital twin, for example, using one or more improvement scheduling rules defined with respect to factors such as, but not limited to, states of different units, types of units, locations of units within the building, combinations thereof, and the like. An example process for incorporating action items into an improvement schedule which may utilize the status data integrated at S380 is described further below with respect to FIG. 4.

In various embodiments, the integrated status data is updated based on changes in the building, for example, as determined based on changes in the tabular data. To this end, the status data may be updated when the corresponding tabular data is accessed.

At optional S390, protocol data is integrated into the digital twin. The protocol data may include, but is not limited to, an order of events and activities that need to happen in order to move from one phase to the other. The protocol data may be utilized to monitor a phase of a building project, for example with respect to action items indicated in the status data. Moreover, the protocol data may be utilized to generate condition reports, recommendations, or both, based on a current status of the building as described herein.

Returning to FIG. 2, at optional S250, one or more simulations are run with respect to the digital twin. More specifically, the simulations are run based on data of the digital twin, and in particular based on the tabular data linked to the digital twin. The simulations may be utilized to simulate aspects related to progress on a building project such as, but not limited to, potential progress at different points in time depending on whether certain action items are completed at certain times, in certain orders, and the like. The simulations may be based on a current status of the building, for example, as determined based on status data integrated in the digital twin of the building as described above with respect to S380.

At S260, one or more visualizations are generated using the digital twin. The visualizations may be generated, for example but not limited to, in response to a request from a user device (e.g., the user device 120, FIG. 1). In an embodiment, S260 includes rendering a three-dimensional visual representation of the digital twin. In a further embodiment, S260 includes generating one or more interactable elements for inclusion in a user interface displaying the visual representation of the digital twin. As a non-limiting example, such interactable elements may allow a user to click on the building or a portion thereof (e.g., a unit in the building) and, when such interaction occurs, tabular data related to the building or portion of the building which the user interacted with may be retrieved and displayed to the user.

In a further embodiment, the visualizations are generated based further on the unit class data structures. More specifically, certain aspects of the visualization may be determined based on values in corresponding fields of the unit class data structures. As a non-limiting example, based on fields of unit class data structures related to completion of certain action items, a status of each unit may be determined, and a visual representation such as a color of the unit to be rendered is determined. In some implementations, a user may interact with the visualization in order to update such visually indicated information (e.g., to change a status of a unit). In such implementations, changes made via a user interface displaying the visualization may be utilized to update the tabular data accordingly to reflect those changes.

When simulations are run at S250, the visualizations may be generated based further on results of the simulations. For example, simulation results may include values related to building progress which may be incorporated into data displayed when the digital twin is interacted with (e.g., via a graphical user interface). Moreover, simulation results related to particular units or groups of units may be incorporated into the display elements representing the digital twin such that simulation results related to a given unit or group of units is displayed when a user interacts with that unit or group of units via a graphical user interface displaying the 3D model of the digital twin and its units.

At optional S270, one or more recommendations for optimization are generated based on the digital twin. The recommendations may include, but are not limited to, recommendations for meeting one or more target goals or otherwise optimizing building development. Alternatively, or in combination, the recommendations may include recommendations for optimizing utilization of completed portions of the building (e.g., fully renovated units or floors). The recommendations may further be defined with respect to the digital twin (e.g., by indicating portions of the building represented in a visualization of the digital twin such that the recommendation is visually presented to the user), with respect to an improvement schedule for the digital twin, or both.

In an embodiment, the optimization recommendations may be generated based further on the simulation results. As a non-limiting example, when the simulation results indicate that a proposed improvement schedule will not be feasible (e.g., when the simulations yield a rate of successfully completing all applicable actions within a target end date of a building project that is below a predetermined threshold such as less than 50% success rate), a recommendation may be generated to prioritize certain action items in order to improve the chance of successfully meeting the target.

FIG. 4 is a flowchart 400 illustrating a method for generating user interfaces based on condition reports defined with respect to a digital twin according to an embodiment. In an embodiment, the method is performed by the digital twin manager 130, FIG. 1.

At S410, target data is received. The target data indicates a building for which a condition report may be desired and may be received, for example, from a user device (e.g., the user device 120, FIG. 1) via one or more inputs provided by a user of the user device. The target data further indicates one or more target criteria defining a desired state of the building or portions thereof such as, but not limited to, a target end date for completion of the building, target states of the building at different times, target states for particular units or groups of units at different times, combinations thereof, and the like.

At S420, a digital twin is identified based on the target data. The digital twin may be a digital twin corresponding to a building indicated in the target data.

At S430, an improvement schedule is determined based on the digital twin and the target data. In an embodiment, S430 includes applying one or more improvement scheduling rules defined with respect to factors such as, but not limited to, states of different units, types of units, locations of units within the building, target characteristics for the building, combinations thereof, and the like. In a further embodiment, S430 includes determining a timeline for improvements defined with respect to action items to be performed in order to realize one or more target states or characteristics for the building. To this end, in yet a further embodiment, S430 may include determining a set of action items to be performed according to the improvement schedule.

At S440, one or more improvement action items are presented based on the determined improvement schedule. In an embodiment, the presented action items include the set of action items to be performed according to the improvement schedule. In this regard, a user to whom the action items are presented may view and select, organize, or otherwise manipulate the action items via a user interface, thereby arranging the action items into respective portions of the schedule (e.g., scheduling certain action items to be performed during certain time periods defined as part of the schedule).

At S450, one or more inputs indicating action items for the improvement schedule are received. The inputs may be user inputs received, for example, from the user device. Such inputs may be or may include, but are not limited to, selections of action items. As noted above, such selections and other inputs may be utilized to determine where certain action items should be placed within the improvement schedule (e.g., which periods of time certain action items should be performed in). As a non-limiting example, for an improvement schedule made of various weeks as the time periods, a selection of an action item “Room divisions” representing an activity of defining divisions of units into subunits in the form of rooms may be selected by a user and placed within “Week 2” of the improvement schedule such that the user has scheduled the “Room divisions” activity for the second week of a building project.

In some embodiments, S450 includes updating at least a portion of the tabular data for the building based on the action item inputs. In this regard, user interactions or other interactions yielding such action item inputs may serve to trigger updates to the tabular data which, in turn, will cause the digital twin of the building to be updated in accordance with the updates to the tabular data caused by the action item inputs. In particular, in some embodiments, the updates to the tabular data based on the action item inputs may be or may include changes to condition of respective portions of the building based on the action item inputs (e.g., units or groups of units that were interacted with as reflected in the action item inputs).

At S460, the action items indicated in the inputs received at S450 are integrated into the improvement schedule. As noted above, the action items may be integrated based on further user inputs such as dragging and dropping an icon representing a given action item into an area of a user interface showing an icon representing a given portion of the improvement schedule (e.g., a given time period of the improvement schedule).

At S470, a condition report is generated using the digital twin based on the received action item inputs. In an embodiment, the condition report indicates one or more states, characteristics, or other conditions of the building with respect to the applicable action items. For example, the condition report may indicate whether a current condition of the building indicates that each action item has been performed.

In an embodiment, S470 includes accessing the digital twin. As noted above, when the digital twin is linked to underlying tabular data and is accessed, the digital twin may be populated with data from among the tabular data, thereby updating the digital twin to reflect a current state of the building as represented in the current tabular data. To this end, S470 may include accessing the linked tabular data (e.g., by accessing data at a location of the applicable tabular data in storage referenced in the digital twin). Alternatively, when the digital twin is accessed, another system that manages the digital twin may access the underlying tabular data in order to populate the digital twin and return the populated digital twin.

At S480, one or more user interface components are generated based on the condition report. The user interface components may include, but are not limited to, components showing the building (e.g., showing the three-dimensional model of the digital twin. The user interface components may further be visually distinguished based on conditions of respective portions of the building. As a non-limiting example, portions of the building which meet one or more target criteria may be colored green and portions of the building which do not meet any of the target criteria may be colored red, thereby reflecting that certain portions of the building are in a desired condition and other portions of the building are not in the desired condition. In a further embodiment, the user interface components may include interactable components such as, but not limited to, icons that, when interacted with, cause display of more details of the condition report (e.g., a detailed explanation of which units or other portions fail to meet which target conditions).

At S490, a user interface including at least a portion of the generated interface components is caused to be displayed. In an embodiment, S490 includes sending the user interface components to, for example, the user device for display. In another embodiment, S490 includes displaying a user interface including one or more of the user interface components.

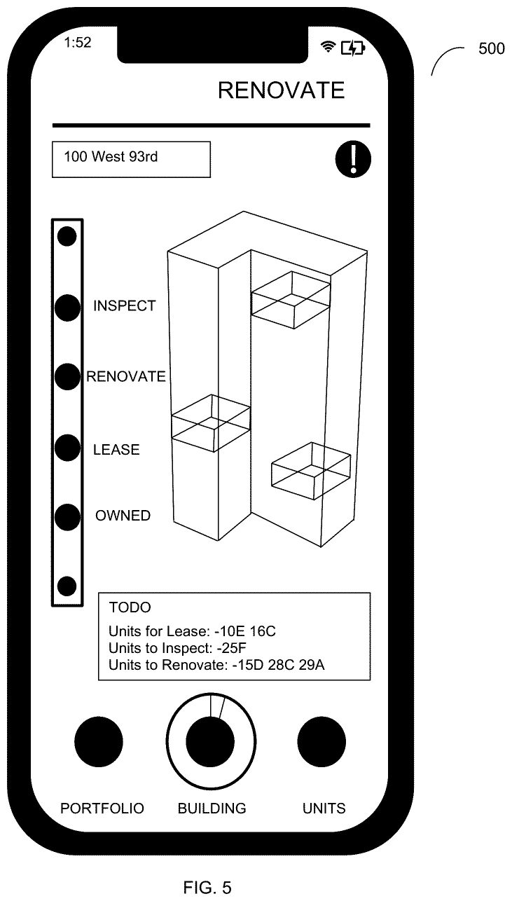

FIG. 5 is an example illustration 500 of a digital twin integrated with tabular data. The illustration 500 demonstrates a view of a display showing a three-dimensional model of a building including various units. The particular non-limiting example shown in FIG. 5 depicts a “RENOVATE” mode which may, for example, visually distinguish units in a renovation phase of a building development.

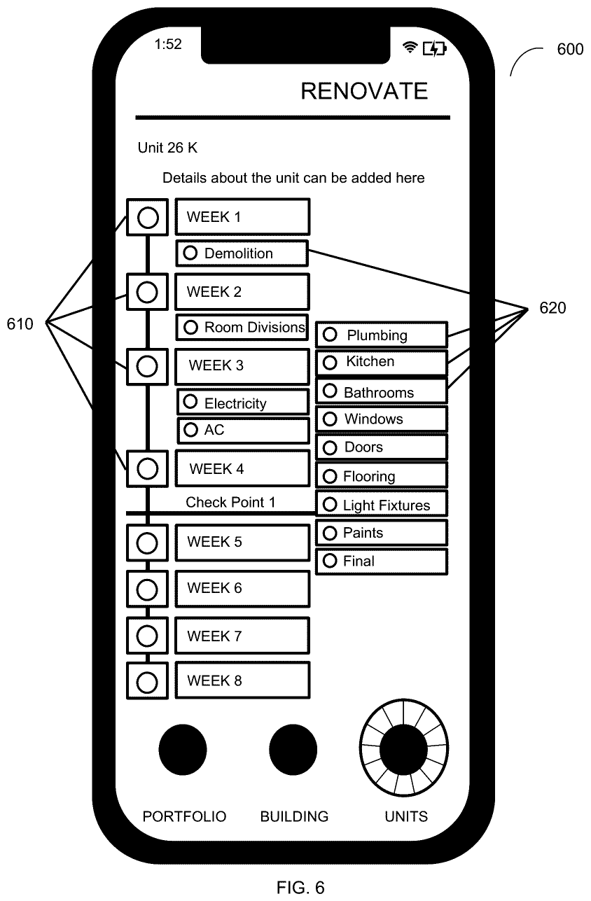

FIG. 6 is an example illustration 600 of a renovation schedule integrating action items. The illustration 600 demonstrates a visual representation of an improvement schedule, for example as discussed above with respect to S430 through S460. The illustration 600 further includes various temporal icons 610 and various action item icons 620. Each temporal icon 610 represents a respective time of an improvement schedule such as, but not limited to, respective weeks of a building development project. Each action item 620 represents an action item such as, but not limited to, action items required to move to a next phase of a building development project. As shown in the non-limiting example illustration 600, example action items include demolition, room divisions, electricity, air conditioning (AC), plumbing, kitchen, bathrooms, windows, doors, flooring, light fixtures, painting, and final touchups.

The action item icons 620 may be interacted with via a user device (e.g., by clicking and dragging) in order to select the action items to be integrated into the improvement schedule, to place action items into respective times of the improvement schedule (e.g., time periods represented by the temporal icons 610), both, and the like, thereby allowing a user to customize the improvement schedule accordingly. The digital twin may be monitored based on an improvement schedule customized in this manner in order to enable features such as, but not limited to, alerting when a project is behind schedule (e.g., when the digital twin does not reflect improvements corresponding to action items for a given period of time which has passed), generating recommendations for completing a project (e.g., recommendations of when action items might need to be started in order to keep the project on schedule, recommendations of an order in which units should be improved via action items in order to optimize use of the units), both, and the like.

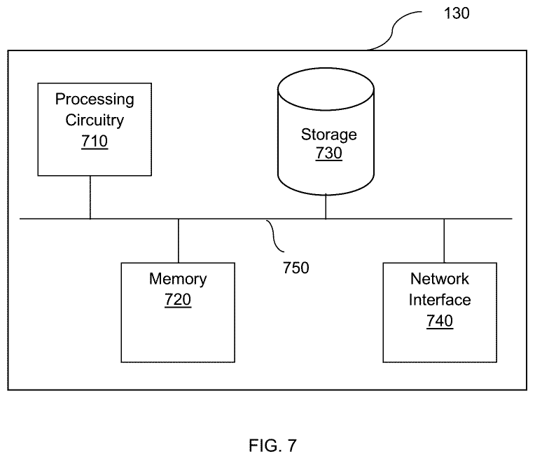

FIG. 7 is an example schematic diagram of a digital twin manager 130 according to an embodiment. The digital twin manager 130 includes a processing circuitry 710 coupled to a memory 720, a storage 730, and a network interface 740. In an embodiment, the components of the digital twin manager 130 may be communicatively connected via a bus 750.

The processing circuitry 710 may be realized as one or more hardware logic components and circuits. For example, and without limitation, illustrative types of hardware logic components that can be used include field programmable gate arrays (FPGAs), application-specific integrated circuits (ASICs), Application-specific standard products (ASSPs), system-on-a-chip systems (SOCs), graphics processing units (GPUs), tensor processing units (TPUs), general-purpose microprocessors, microcontrollers, digital signal processors (DSPs), and the like, or any other hardware logic components that can perform calculations or other manipulations of information.

The memory 720 may be volatile (e.g., random access memory, etc.), non-volatile (e.g., read only memory, flash memory, etc.), or a combination thereof.

In one configuration, software for implementing one or more embodiments disclosed herein may be stored in the storage 730. In another configuration, the memory 720 is configured to store such software. Software shall be construed broadly to mean any type of instructions, whether referred to as software, firmware, middleware, microcode, hardware description language, or otherwise. Instructions may include code (e.g., in source code format, binary code format, executable code format, or any other suitable format of code). The instructions, when executed by the processing circuitry 710, cause the processing circuitry 710 to perform the various processes described herein.

The storage 730 may be magnetic storage, optical storage, and the like, and may be realized, for example, as flash memory or other memory technology, compact disk-read only memory (CD-ROM), Digital Versatile Disks (DVDs), or any other medium which can be used to store the desired information.

The network interface 740 allows the digital twin manager 130 to communicate with, for example, the user device 120, the data sources 140, and the like.

It should be understood that the embodiments described herein are not limited to the specific architecture illustrated in FIG. 7, and other architectures may be equally used without departing from the scope of the disclosed embodiments.

It is important to note that the embodiments disclosed herein are only examples of the many advantageous uses of the innovative teachings herein. In general, statements made in the specification of the present application do not necessarily limit any of the various claimed embodiments. Moreover, some statements may apply to some inventive features but not to others. In general, unless otherwise indicated, singular elements may be in plural and vice versa with no loss of generality. In the drawings, like numerals refer to like parts through several views.

The various embodiments disclosed herein can be implemented as hardware, firmware, software, or any combination thereof. Moreover, the software may be implemented as an application program tangibly embodied on a program storage unit or computer readable medium consisting of parts, or of certain devices and/or a combination of devices. The application program may be uploaded to, and executed by, a machine comprising any suitable architecture. Preferably, the machine is implemented on a computer platform having hardware such as one or more central processing units (“CPUs”), a memory, and input/output interfaces. The computer platform may also include an operating system and microinstruction code. The various processes and functions described herein may be either part of the microinstruction code or part of the application program, or any combination thereof, which may be executed by a CPU, whether or not such a computer or processor is explicitly shown. In addition, various other peripheral units may be connected to the computer platform such as an additional data storage unit and a printing unit. Furthermore, a non-transitory computer readable medium is any computer readable medium except for a transitory propagating signal.

All examples and conditional language recited herein are intended for pedagogical purposes to aid the reader in understanding the principles of the disclosed embodiment and the concepts contributed by the inventor to furthering the art, and are to be construed as being without limitation to such specifically recited examples and conditions. Moreover, all statements herein reciting principles, aspects, and embodiments of the disclosed embodiments, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

It should be understood that any reference to an element herein using a designation such as “first,” “second,” and so forth does not generally limit the quantity or order of those elements. Rather, these designations are generally used herein as a convenient method of distinguishing between two or more elements or instances of an element. Thus, a reference to first and second elements does not mean that only two elements may be employed there or that the first element must precede the second element in some manner. Also, unless stated otherwise, a set of elements comprises one or more elements.

As used herein, the phrase “at least one of” followed by a listing of items means that any of the listed items can be utilized individually, or any combination of two or more of the listed items can be utilized. For example, if a system is described as including “at least one of A, B, and C,” the system can include A alone; B alone; C alone; 2A; 2B; 2C; 3A; A and B in combination; B and C in combination; A and C in combination; A, B, and C in combination; 2A and C in combination; A, 3B, and 2C in combination; and the like.

What is claimed is:

1. A method for creating a digital twin using tabular data, comprising:
parsing tabular data representing a plurality of units of a building in order to identify the plurality of units represented in the tabular data;
assigning a unit class data structure of plurality of unit class data structures to each unit of the identified plurality of units, wherein the unit class data structure assigned to each unit stores data for the unit, wherein the unit class data structure assigned to each unit includes at least one field representing at least one characteristic of the unit;
generating a digital twin of the building based on the plurality of unit class data structures and building data for the building, wherein the building data at least represents three-dimensional aspects of the building; and
linking the digital twin to the tabular data based on the plurality of unit class data structures, wherein at least one portion of the digital twin is linked to at least one portion of the tabular data, wherein each linked portion of the tabular data represents a unit of the plurality of units.

2. The method of claim 1, further comprising:
checking a value indicated in each field of at least one first unit class data structure of the plurality of unit class data structures; and
generating a visualization of the digital twin based on the digital twin and each checked value.

3. The method of claim 1, further comprising:
checking a value indicated in each field of at least one first unit class data structure of the plurality of unit class data structures; and
running at least one simulation for the digital twin based on the digital twin and each checked value.

4. The method of claim 1, further comprising:
analyzing the building data for the building in order to identify a plurality of polylines of the building, wherein each polyline is a vector line including at least one connected line segment, wherein the at least one connected line segment of each polyline forms a shape.

5. The method of claim 4, wherein creating the digital twin further comprises:
extruding each of the plurality of polylines in order to create a plurality of three-dimensional (3D) models of the plurality of units, wherein the digital twin is generated based further on the plurality of 3D models of the plurality of units.

6. The method of claim 5, further comprising:
coding the plurality of 3D models with a plurality of names, wherein the plurality of names is determined based on a plurality of identifiers of the plurality of units indicated in the tabular data.

7. The method of claim 4, further comprising:
matching the plurality of units to respective portions of the building data based on the plurality of polylines, wherein the digital twin is created based on the matching between the plurality of units and the respective portions of the building data.

8. The method of claim 1, further comprising:
generating a plurality of grouping class data structures based on the plurality of unit class data structures, wherein each grouping class data structure represents a subset of the unit class data structures, wherein changes made with respect to each grouping class data structure are applied to each of the subset of the unit class data structures represented by the grouping class data structure; and
applying a change to a first grouping class data structure of the plurality of grouping class data structures.

9. The method of claim 1, further comprising:
accessing the digital twin, wherein accessing the digital twin further comprises populating the digital twin with data from each of the linked at least one portion of the tabular data.

10. The method of claim 1, further comprising:
generating a condition report based on the digital twin and at least one action item input, wherein the condition report indicates a condition of at least one portion of the building.

11. The method of claim 10, further comprising:
updating at least a portion of the tabular data based on at least one action item input, wherein the condition report is generated based further on the updated at least a portion of the tabular data.

12. The method of claim 10, further comprising:
generating at least one user interface component based on the condition report, wherein at least a portion of the at least one user interface component is visually distinguished based on the condition of the at least one portion of the building indicated by the condition report.

13. A non-transitory computer readable medium having stored thereon instructions for causing a processing circuitry to execute a process, the process comprising:
parsing tabular data representing a plurality of units of a building in order to identify the plurality of units represented in the tabular data;
assigning a unit class data structure of plurality of unit class data structures to each unit of the identified plurality of units, wherein the unit class data structure assigned to each unit stores data for the unit, wherein the unit class data structure assigned to each unit includes at least one field representing at least one characteristic of the unit;
generating a digital twin of the building based on the plurality of unit class data structures and building data for the building, wherein the building data at least represents three-dimensional aspects of the building; and
linking the digital twin to the tabular data based on the plurality of unit class data structures, wherein at least one portion of the digital twin is linked to at least one portion of the tabular data, wherein each linked portion of the tabular data represents a unit of the plurality of units.

14. A system for creating a digital twin using tabular data, comprising:
a processing circuitry; and
a memory, the memory containing instructions that, when executed by the processing circuitry, configure the system to:
parsing tabular data representing a plurality of units of a building in order to identify the plurality of units represented in the tabular data;
assigning a unit class data structure of plurality of unit class data structures to each unit of the identified plurality of units, wherein the unit class data structure assigned to each unit stores data for the unit, wherein the unit class data structure assigned to each unit includes at least one field representing at least one characteristic of the unit;
generating a digital twin of the building based on the plurality of unit class data structures and building data for the building, wherein the building data at least represents three-dimensional aspects of the building; and
linking the digital twin to the tabular data based on the plurality of unit class data structures, wherein at least one portion of the digital twin is linked to at least one portion of the tabular data, wherein each linked portion of the tabular data represents a unit of the plurality of units.

15. The system of claim 14, wherein the system is further configured to:
check a value indicated in each field of at least one first unit class data structure of the plurality of unit class data structures; and
generate a visualization of the digital twin based on the digital twin and each checked value.

16. The system of claim 14, wherein the system is further configured to:
check a value indicated in each field of at least one first unit class data structure of the plurality of unit class data structures; and
run at least one simulation for the digital twin based on the digital twin and each checked value.

17. The system of claim 14, wherein the system is further configured to:
analyze the building data for the building in order to identify a plurality of polylines of the building, wherein each polyline is a vector line including at least one connected line segment, wherein the at least one connected line segment of each polyline forms a shape.

18. The system of claim 17, wherein the system is further configured to:
extrude each of the plurality of polylines in order to create a plurality of three-dimensional (3D) models of the plurality of units, wherein the digital twin is generated based further on the plurality of 3D models of the plurality of units.

19. The system of claim 18, wherein the system is further configured to:
code the plurality of 3D models with a plurality of names, wherein the plurality of names is determined based on a plurality of identifiers of the plurality of units indicated in the tabular data.

20. The system of claim 17, wherein the system is further configured to:
match the plurality of units to respective portions of the building data based on the plurality of polylines, wherein the digital twin is created based on the matching between the plurality of units and the respective portions of the building data.

21. The system of claim 14, wherein the system is further configured to:
generate a plurality of grouping class data structures based on the plurality of unit class data structures, wherein each grouping class data structure represents a subset of the unit class data structures, wherein changes made with respect to each grouping class data structure are applied to each of the subset of the unit class data structures represented by the grouping class data structure; and
apply a change to a first grouping class data structure of the plurality of grouping class data structures.

22. The system of claim 14, wherein the system is further configured to:
access the digital twin, wherein accessing the digital twin further comprises populating the digital twin with data from each of the linked at least one portion of the tabular data.

23. The system of claim 14, wherein the system is further configured to:
generate a condition report based on the digital twin and at least one action item input, wherein the condition report indicates a condition of at least one portion of the building.

24. The system of claim 23, wherein the system is further configured to:
update at least a portion of the tabular data based on at least one action item input, wherein the condition report is generated based further on the updated at least a portion of the tabular data.

25. The system of claim 23, wherein the system is further configured to:
generate at least one user interface component based on the condition report, wherein at least a portion of the at least one user interface component is visually distinguished based on the condition of the at least one portion of the building indicated by the condition report.
